(19) United States
(12) Patent Application Publication
(10) Pub. No.: US 2002/0189662 A1
(43) Pub. Date: Dec. 19, 2002

(54) Device for producing solar energy and water

(76) Inventor: Holger Lomparski, Bous (DE)

Correspondence Address: Nixon & Vanderhye, 1100 North Glebe Road 8th Floor, Arlington, VA, 22201-4714, US

(21) Appl. No.: 10/148,679

(22) PCT Filed: Nov. 30, 2000
(86) PCT No.: PCT/EP00/12044

(30) Foreign Application Priority Data
Dec. 2, 1999 (DE) 199 58 079.0

(51) Int. Cl. H01L 31/00

(52) U.S. Cl. 136/246; 136/244; 136/251; 136/291

(57) ABSTRACT

The invention relates to an improved device for producing and/or providing solar energy and water, with the following characteristics: at least one modular photovoltaic element (25) is provided, said photovoltaic element (25) is positioned beneath transparent cover plate (41) which can be directed towards the sun, at least one cooling device (31) is also provided for cooling the thereto, the cooling device (31) also has a modular construction and the photovoltaic

The invention relates to a device for producing solar energy and water.

Producing energy and water represents a basic problem in the long term, nationally and internationally.

Energy consumption at present is still based for the major part on the combustion of fossil fuels. As a result, these fossil sources of energy are not only being used up but, above all, also contribute to an environmental loading which is no longer to be tolerated. On this basis, increasingly greater approval is being given to trends, firstly to have recourse to renewable energy sources, or else alternatively to use energy producing devices to a far greater extent. In addition to thermal power stations and wind energy, solar energy is of great importance.

An appropriate device has been disclosed, for example, by DE 34 12 584 A1. According to this prior publication, a solar power plant is described which comprises a large number of modular units of photovoltaic cells which are divided up into areas and which, for example, is arranged over a roadway as a roof, following the roadway. A large number of such areas can in this case be erected in a grid-like arrangement on an area—in each case on its own supporting framework—the individual areas being arranged like the bays of a shed roof, that is to say the envelope curve is a sawtooth line. If the sun shines substantially transversely with respect to the erected plant, then in terms of alignment with the sun, the base can also be constructed as a continuous roof area.

The bays conceived in this way are used at the same time also as a protection against rain water which is associated in particular with advantages for the traffic routes located underneath.

The object of the present invention is to provide a comparatively improved device for producing solar energy and water.

According to the invention, the object is achieved in accordance with the features specified in claim 1. Advantageous refinements of the invention are specified in the subclaims.

As compared with conventional solutions, the device according to the invention for producing solar energy and water has considerable advantages.

This is because, beside the modular photovoltaic elements, the invention additionally provides at least one modularly constructed cooling device for the photovoltaic elements. As a result, the production or yield of electrical energy may specifically be increased considerably. This is because warming of the photovoltaic elements results in their reduced efficiency.

In a particularly preferred embodiment, therefore, a modular thermal and/or solar collector is provided, which is arranged underneath the modular photovoltaic element. This thermal and solar collector is used for the additional production of heat, which is ultimately effected by the solar heating. As a result of transporting the heat away, however, at the same time cooling for the photovoltaic elements is implemented, in order to increase their efficiency.

Alternatively or additionally, however, another or a further cooling device can also be provided, for example a cooling device, through which liquid and/or gaseous cooling media flow, for the photovoltaic elements. For this purpose, a space is preferably formed between the glass roofing located on the sun side and the upper side of the photovoltaic elements. A preferably gaseous cooling medium, for example air, can flow through this space. Said air, can, for example, be pre-cooled. The action of the through-flow of cooling air is preferably based on a type of “chimney effect”, which can be implemented by the corresponding modular energy and water production elements being erected with an inclination with respect to the horizontal. As a result of the heating, the warmed air can then rise upward and be carried away, so that automatically relatively cooler air enters the flow channel from a lower inflow opening.

The aforementioned translucent plate or covering lying on the sun side leads to a light-amplifying effect, since the light let through the translucent covering and possible thrown back by the photovoltaic cells lying underneath is reflected again. This leads to an increase in the efficiency.

In a development of the invention, provision is made for the translucent covering to be provided with a slippery coating, which prevents soiling and ensures additional drainage of water. The aforementioned solar or thermal collectors comprises at least one line, but preferably has a plurality of preferably integrated lines, in order to dissipate the thermal energy that accumulates. Here, too, for the purpose of thermal dissipation and therefore for the cooling of the photovoltaic elements, gaseous and also liquid media can be used.

The entire system is constructed modularly. In this case, modules are preferably used which comprise photovoltaic elements together with the solar and thermal collectors as a component which can be handled in a uniform way. Finally, the aforementioned glass covering arranged and constructed at a distance above the photovoltaic elements (for example in the form of spacers) is also part of such a module.

Furthermore, it proves to be beneficial if the modules are provided with appropriate plug-in and/or screw connections from the start, in order to join such units directly to one another without problems. At the connection points, connecting plug-in connections and/or connecting screw connections can be provided as required. If required, separate lines can also be arranged at the connections. As a result, large areas can be combined and linked to form an overall system.

In order to improve the production of water with simple means, the connecting devices for the modules can comprise water collecting devices, comparable with roof gutters. Preferably, however, use is made of water discharge gutters with coverings made of corrugated gratings, which can consist of the same material as the water gutters. As a result, the rain water caught over the upper side of the modules, as a rule the aforementioned translucent glass coverings, can be caught directly via the connectable water discharge gutters with the water-permeable corrugated gratings arranged above them and, for example, can be led away to water collecting devices, water collecting basins, pumping stations or the like.

The device according to the invention can be erected anywhere. It can preferably be implemented over public traffic routes and streets, in particular motorways, country roads or else rail tracks. In an overall plant of this type, it is therefore possible for the solar energy to be utilized with high efficiency, since the solar energy can be converted directly into electrical power. This electrical power can relatively easily be conveyed onward via lines provided. If appropriate, the power can at least also be used directly for lighting systems, traffic light systems provided on site.

However, the solar energy is also utilized in a supplementary manner, from a thermal point of view, by means of the solar or thermal collectors used, since by means of the circulating medium heated in this way, for example district heating can be made available. To this extent, the system can also be coupled to a heat pump.

Finally, the modules are suitable for collecting rain water. In a roofed-over design, as a result the streets, tracks, public squares etc. located underneath them are protected against the influences of weather.

The invention will be explained in more detail below using drawings, in which, in detail:

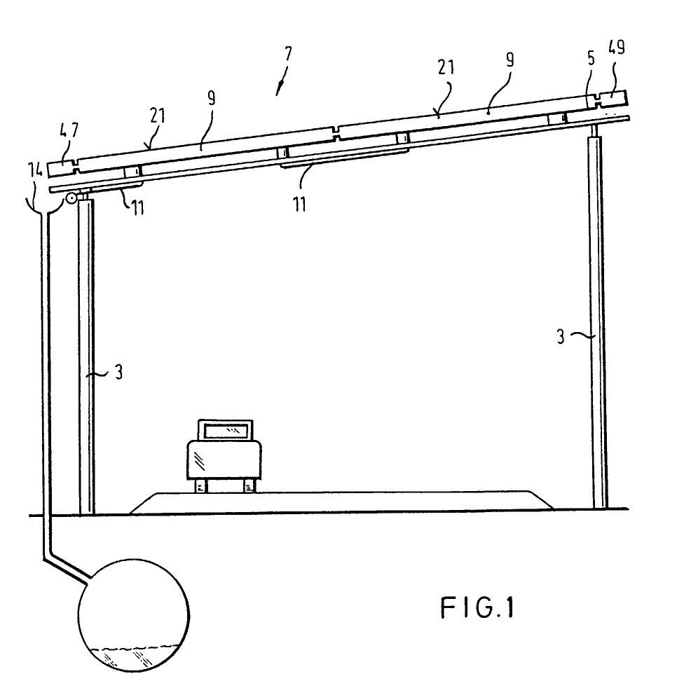

FIG. 1 shows a schematic sketch in cross section relating to a device for producing solar energy and water over the track of a roadway;

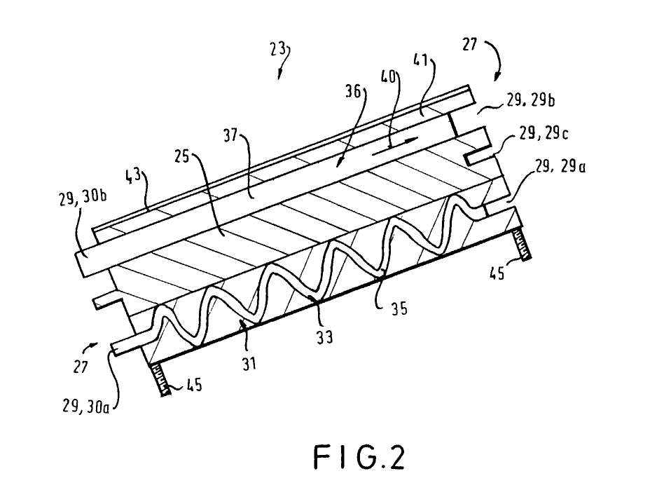

FIG. 2 shows a schematic cross-sectional illustration through a modularly constructed solar energy and water production element;

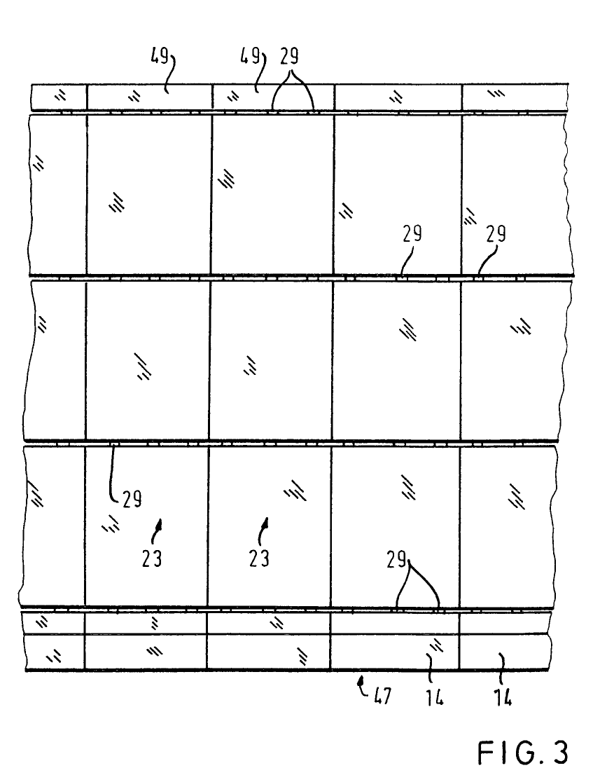

FIG. 3 shows a schematic plan view of a plurality of combined solar energy and water production modules;

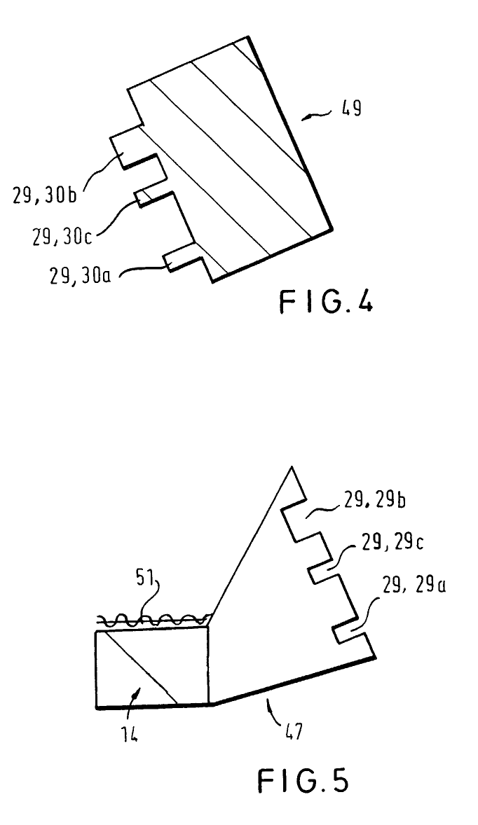

FIG. 4 shows a plug-in connecting element as a lower limiting element with a rainwater catching gutter; and

FIG. 5 shows a corresponding, upper plug-in or termination element for the modularly constructed solar energy or water production elements.

In the schematic cross-sectional illustration, an overland street 1 is shown, along which, on both sides at intervals, columns 3 are provided above which roof-like supports 5, possibly spaced apart from one another, are formed. On these supports, the modules 21 further explained below can be constructed and anchored, ultimately a roof 7 also being formed at the same time by the upper side of the modules 21.

In the following text, reference is made to FIGS. 2 and following, in which the individual modules for the energy and water production elements are shown.

A corresponding module 23 therefore comprises a modular photovoltaic element 25 which, on its opposite module sides 27 and/or its module sides located offset through 90° thereto and lying on the left or right can be provided with connections 29, in particular plug-in connections (if required but additionally or alternatively also with screw connections or the like), in order to couple the module to a next module. In this case, the plug-in connections on one connection side 27 are preferably plug-like and on the opposite connection side are socket-like, in order to be able to cascade corresponding modules by plugging them together, that is to say to join them without problems to form larger functional units.

Also provided is a cooling device 31 for the photovoltaic elements 25, the cooling device 31 in the exemplary embodiment shown comprising a thermal or solar collector element 33 located underneath the photovoltaic element 25, that is to say facing away from the sun. Said element has a through-flow device 35, in the form for example of one or more flow lines, which can be laid rectilinearly, in meandering fashion, in the form of loops or helices, to be specific from a connection 29a on the inlet side to a connection 30a on the outlet side. The connections 29a and 30a can likewise be constructed as plug-in connections, but if required, however, also alternatively or additionally as screw connections or the like.

In this case, the cooling device 31 comprises a further cooling measure, namely a further cooling device 36 also provided above the photovoltaic elements 25. This cooling device is constructed in the manner of a through-flow device 37 through which liquid and/or gaseous media can flow. However, a through flow with gaseous media, in particular air, is preferably provided. To this end, the through-flow device 37 comprises a space 39 between the underside of the translucent covering plate 41 located on the sun side and the upper side of the photovoltaic element 25 located underneath. In particular in the event of inclined erection in the manner of a roof, the result is therefore a chimney effect with the result that, with heating of the air or of the other coolant in the space 39, said air or other coolant attempts to rise upward in the direction of arrow 40 and, in the process, takes in cooler flow medium from the underside. To this end, a connection or outlet 29b is preferably formed on the upper side and a connection or inlet 30b is preferably formed on the underside, in order for example to permit the air to flow in there.

Here, too, the connections are again formed as pure plug-in connections, but if required, additionally or alternatively, can be provided as screw connections or the like.

For completeness, it is also noted finally that the photovoltaic element 25 is likewise provided with one or more plug-in connections formed on the two opposite connecting sides, in particular electrical plug-in devices 29c and 30c, in order to be able to plug the photovoltaic element 25 directly together with an adjacent next element and to make electrical contact therewith.

As the design shows, preferably all the connections 29, 29a, 29b and also the connections 30, 30a, 30b are provided lying in the same direction on the opposite connection sides, so that corresponding modules 23 can be combined into large-area plant groups merely only by being plugged together. In this case, the modules, in plan view, do not necessarily have to have a rectangular shape but, for example, can also be configured hexagonally. Use is therefore preferably made of shapes which can be joined together to form large-area, self-contained units and to implement the most self-contained possible covering 7.

The translucent covering plate 41 is formed in such a way that the sunlight reflected back from the photovoltaic element is thrown back again at the underside, that is to say contributes to a high energy yield as a result. In order largely to avoid or to reduce soiling on the outer side, there the translucent covering 41 can [lacuna] with an appropriate coating, in particular a slippery coating 43. The units provided in this way can be fitted and mounted on an appropriate load-bearing construction 3, 5 via spacers, screws or the like.

As emerges in particular from the schematic plan view of an extract according to FIG. 3, as already explained, the modules are combined as an overall module. At the edge regions, for example, termination devices 47 can be connected, which are preferably formed as a termination plug-in device 47. As a result, at the points at which no module is plugged on in the connection direction, a connection to a laterally adjacent module is implemented, to the extent that this is necessary. As a result, therefore, a self-contained coolant circuit to a next adjacent thermal or solar collector element 33 can be produced, if a series connection is desired. In exactly the same way, a connection to a next adjacent photovoltaic element can be implemented via an electrical plug-in connection. The same in principle also applies to the upper cooling device 31, formed in the manner of a through-flow channel, whereby here, in particular when ambient air is used as cooling, only an outlet channel is provided in the termination element 47, in order to discharge the warm air into the surroundings.

The lower termination elements 49 are formed in a similar way, it being possible for these preferably also to be provided with a water drainage gutter 14, according to FIG. 3. According to FIG. 4, the gutter is of box-like shape in cross section (but can also have any other cross-sectional shape). Preferably formed on the upper side of the drainage gutter is a corrugated grating 51, which lets through the rain water running off over the covering without problems to the drainage gutter, but that at the same time ensures a certain amount of protection against soiling, dirtying by leaves etc. A highly schematic, simplified cross-sectional illustration of an upper and a lower termination element 47 and 49, respectively, is shown in drawings 4 and 5.

As also emerges from the illustration of the appended drawings, the modules are preferably combined from top to bottom in the plug-in direction following a roof line, and at the upper and lower end are connected, via the aforementioned termination plug-in devices or general termination connecting devices 47, 49, to a roof-like covering formed in this way in the continuous direction.

The power obtained can be used without problems to feed into the electrical network of electrically driven trains (electrification of the railroad). In a likewise problem-free and useful manner, the electric energy obtained can be used, for example, to feed magnetic levitation tracks, such as the Transrapid.

However, by means of suitable systems operating with direct current or inductively, electric vehicles can be supplied with electrical energy not only when stationary at special charging stations but also during travel, and charging devices (accumulators, batteries) present on the vehicle can even be charged up additionally, as a result of which the radius and the range is increased considerably as compared with conventional systems restricted only by the size of the batteries. In the case of direct-current line systems, therefore, an electrically conductive contact to the vehicle is produced. In the case of systems operating inductively, this is preferably done without contact.

1. A device for producing and/or providing solar energy and water, having the following features
at least one modular photovoltaic element (25) is provided,
the photovoltaic element (25) is provided underneath a translucent covering plate (41) that can be aligned on the side of the sun, characterized by the following further features
at least one cooling device (31) for cooling the respectively associated photovoltaic element (25) is also provided,
the cooling device (31) is likewise constructed modularly, and
the photovoltaic element (25) and the associated cooling device (31) are constructed as a module (23) that can be handled in a uniform manner.

2. The device as claimed in claim 1, characterized in that the cooling device (31) comprises at least one thermal solar collector element (33), which is arranged to be located underneath the photovoltaic element (25) facing away from the sun.

3. The device as claimed in claim 1 or 2, characterized in that a further cooling device (31) for the photovoltaic element (25) is provided.

4. The device as claimed in claim 1, 2 or 3, characterized in that the cooling device (31) comprises a cooling device (31, 37) through which liquid and/or gaseous cooling medium can flow, which is constructed between the photovoltaic element (25) and the covering plate (41) arranged on the side of the light.

5. The device as claimed in claim 4, characterized in that the cooling device (31, 37) can be flowed through by air, to be specific preferably by utilizing a chimney effect in the case of a module (23) erected obliquely with respect to the horizontal.

6. The device as claimed in one of claims 1 to 5, characterized in that the module (23) that can be handled in a uniform manner comprises, in addition to a photovoltaic element (25) and a thermal and/or solar collector element (33) located underneath, the further cooling device (31, 37) formed in the manner of a through-flow channel between photovoltaic element (25) and covering plate (41) including the covering plate (41).

7. The device as claimed in one of claims 1 to 6, characterized in that the module (23) is provided with connections (29), by which means the module (23) is constructed with the implementation of an electrical connection (29c, 30c) for the photovoltaic element (25), a cooling connection (29a, 30a) for the thermal and/or solar collector element (33) and also a further cooling connection (29b, 30b) for the channel-like through-flow device (35).

8. The device as claimed in one of claims 1 to 7, characterized in that all the connections (29a, 29b, 29b; 30a, 30b, 30c) on the respective connection side of the module (23) are aligned in the direction parallel to one another.

9. The device as claimed in one of claims 1 to 8, characterized in that the connections (29a 29b, 29c; 30a, 30b, 30c) are formed on opposite connection sides.

10. The device as claimed in one of claims 1 to 9, characterized in that in each case a plurality of modules (23) can be connected directly to one another by means of their connections (29a, 29b, 29c; 30a, 30b, 30c).

11. The device as claimed in one of claims 1 to 10, characterized in that on the terminating sides of the modules (23), termination devices (47, 49) are provided, by means of which, if necessary, a connection to an adjacent module (23) can be produced.

12. The device as claimed in one of claims 1 to 11, characterized in that on the lower connection sides of the modules (23), termination devices (47) can be connected, which preferably comprise a rainwater drainage channel (14).

13. The device as claimed in claim 12, characterized in that the rainwater drainage channel (14) comprises a corrugated grating (51) on its upper side.
